(19) United States
(12) Patent Application Publication
(10) Pub. No.: US 2025/0038733 A1
(43) Pub. Date: Jan. 30, 2025

(54) VIBRATION DEVICE AND ELECTRONIC DEVICE

(71) Applicant: Murata Manufacturing Co., Ltd., Nagaokakyo-shi (JP)

(72) Inventor: Shozo OTERA, Nagaokakyo-shi (JP)

(21) Appl. No.: 18/917,368

(22) Filed: Oct. 16, 2024

Related U.S. Application Data
(63) Continuation of application No. PCT/JP2023/017228, filed on May 8, 2023.

(30) Foreign Application Priority Data
May 24, 2022 (JP) 2022-084341

(51) Int. Cl. H03H 9/05; H03H 9/17

(52) U.S. Cl. CPC H03H 9/05; H03H 9/17

(57) ABSTRACT

A vibration device including: a support member that includes a fixed portion, a movable portion having an upper main surface and a lower main surface arranged in an up-down direction, the movable portion constructed to support a vibrated member; an actuator attached to the fixed portion and the movable portion or the vibrated member, and constructed to vibrate the vibrated member in a left-right direction; an elastic coupling portion that elastically couples the fixed portion and the movable portion in a left-right direction, the elastic coupling portion having a first elastic coefficient in the left-right direction and a second elastic coefficient in the up-down direction, and the second elastic coefficient is smaller than the first elastic coefficient.

### CROSS REFERENCE TO RELATED APPLICATIONS

The present application is a continuation of International application No. PCT/JP2023/017228, filed May 8, 2023, which claims priority to Japanese Patent Application No. 2022-084341, filed May 24, 2022, the entire contents of each of which are incorporated herein by reference.

### TECHNICAL FIELD

The present disclosure relates to a vibration device and an electronic device including a vibration device.

### BACKGROUND ART

As an invention related to a conventional vibration device, for example, a vibration structure described in Patent Document 1 is known. The vibration structure described in Patent Document 1 includes a film, a frame member, a vibration unit, a support unit, a first connection member, and a second connection member. The frame member has a frame shape provided with an opening when viewed in a normal direction of the frame member. The vibration unit is located in the opening when viewed in the normal direction of the frame member. The support unit couples the frame member and the vibration unit. When the support unit is elastically deformed, the vibration unit can be displaced with respect to the frame member.

Further, the film has a rectangular shape having a first end portion and a second end portion. The first connection member fixes the first end portion of the film and the vibration unit. The second connection member fixes the second end portion of the film and the frame member.

In the vibration structure having the structure as described above, when voltage is applied to the film, the film is deformed so that a distance between the first end portion and the second end portion changes. By the above, the vibration unit vibrates with respect to the frame member.
Patent Document 1: Japanese Patent No. 6662496

### SUMMARY OF THE DISCLOSURE

In the vibration structure described in Patent Literature 1, there is a demand for improving fall resistance of the vibration structure.

In view of the above, an object of the present disclosure is to provide a vibration device and an electronic device in which fall resistance of the vibration device can be improved.

A vibration device according to an embodiment of the present disclosure is a vibration device including: a support member that includes a fixed portion, a movable portion having an upper main surface and a lower main surface arranged in an up-down direction, the movable portion constructed to support a vibrated member; an actuator attached to the fixed portion and the movable portion or the vibrated member, and constructed to vibrate the vibrated member in a left-right direction; an elastic coupling portion that elastically couples the fixed portion and the movable portion in a left-right direction, the elastic coupling portion having a first elastic coefficient in the left-right direction and a second elastic coefficient in the up-down direction, and the second elastic coefficient is smaller than the first elastic coefficient.

In the present description, directions are defined as below. In FIGS. 1 to 5, an up-down direction is a direction in which a normal line of an upper main surface US32 of a movable portion 32 extends. In FIGS. 1 to 5, a left-right direction is a direction in which an actuator 4 vibrates a vibrated member 2. In FIGS. 1 to 5, a front-rear direction is a direction in which a first curved portion 331, a second curved portion 332, or a third curved portion 333 projects. The up-down direction, the left-right direction, and the front-rear direction are orthogonal to each other. Note that the definition of directions in the present description is an example. Therefore, a direction at the time of actual use of a vibration device 10 does not need to coincide with a direction in the present description.

Hereinafter, X and Y represent components or members of an electronic device 100. In the present description, each part of X is defined as below unless otherwise specified. An upper part of X means the upper half of X. An upper end of X means an end in an upward direction of X. An upper end portion of X means an upper end and the vicinity of the upper end of X. This definition also applies to directions other than the upward direction.

Further, “X is located above Y” means that X is located directly above Y. Therefore, X overlaps Y when viewed in the up-down direction. “X is located higher than Y” means that X is located directly above Y and that X is located diagonally above Y. Therefore, X may or may not overlap Y when viewed in the up-down direction. This definition also applies to directions other than the upward direction.

According to the vibration device of the present disclosure, fall resistance of the vibration device can be improved.

### BRIEF EXPLANATION OF THE DRAWINGS

FIG. 1 is a sectional view of an electronic device 100 as viewed in a front direction.

FIG. 2 is a plan view of a vibration device 10 as viewed in a downward direction.

FIG. 3 is a plan view of a support member 3 as viewed in the downward direction.

FIG. 4 is a plan view of an elastic coupling portion 33 as viewed in the downward direction.

FIG. 5 is a plan view of an actuator 4 as viewed in the downward direction.

FIG. 6 is a sectional view illustrating a situation in which a vibration device 1010 according to a comparative example falls and the vibration device 1010 according to the comparative example collides with a floor 6 in a state in which a fixed portion 31 is above a movable portion 32.

FIG. 7 is a sectional view illustrating directions of forces F1, F2, and F3 when the vibration device 10 collides with the floor 6 in a state where the fixed portion 31 is above the movable portion 32.

### DESCRIPTION OF THE PREFERRED EMBODIMENTS

### Embodiment

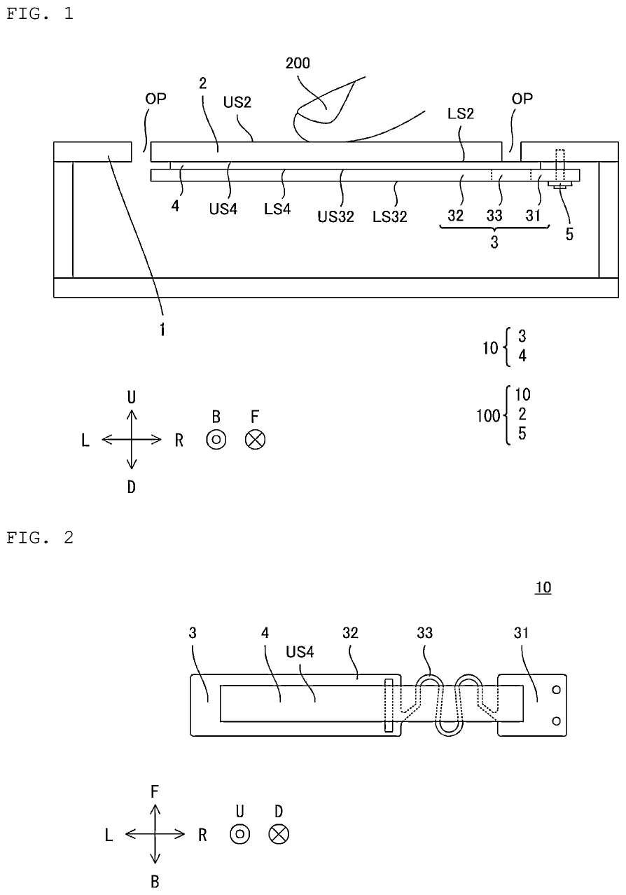

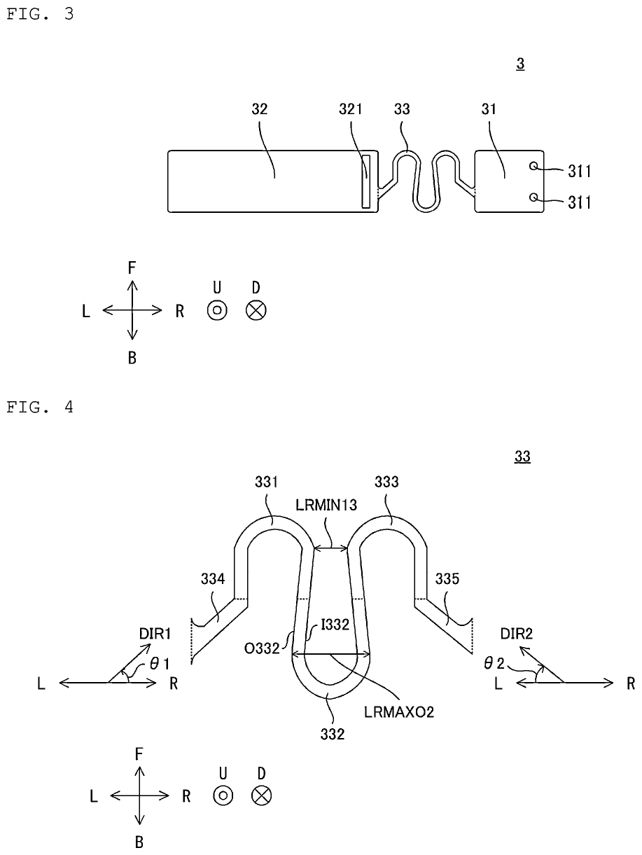

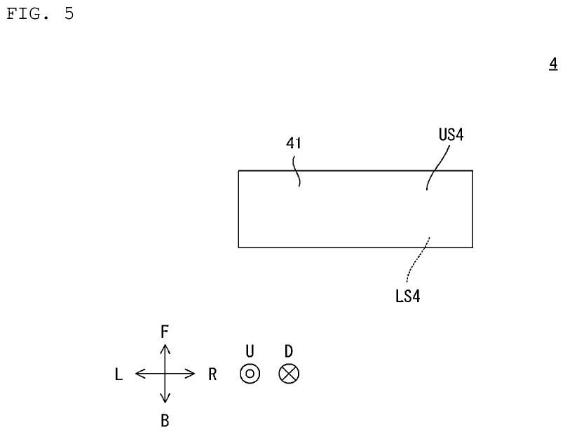

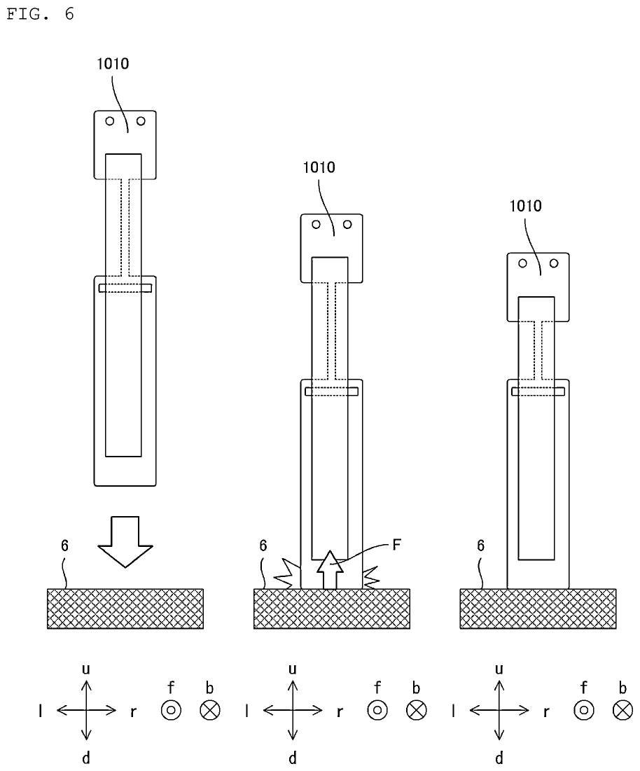

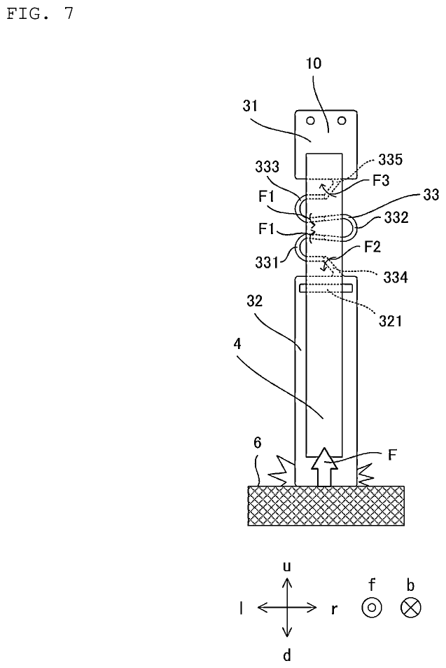

Hereinafter, a configuration of a vibration device 10 according to an embodiment of the present disclosure will be described with reference to the drawings. FIG. 1 is a sectional view of an electronic device 100 as viewed in a front direction. FIG. 2 is a plan view of the vibration device 10 as viewed in a downward direction. FIG. 3 is a plan view of a support member 3 as viewed in the downward direction. FIG. 4 is a plan view of an elastic coupling portion 33 as viewed in the downward direction. FIG. 5 is a plan view of an actuator 4 as viewed in the downward direction. FIG. 6 is a sectional view illustrating a situation in which a vibration device 1010 according to a comparative example falls and the vibration device 1010 according to the comparative example collides with a floor 6 in a state in which a fixed portion 31 is above a movable portion 32. FIG. 7 is a sectional view illustrating directions of forces F1, F2, and F3 when the vibration device 10 collides with the floor 6 in a state where the fixed portion 31 is above the movable portion 32.

As illustrated in FIG. 1, as an example, the vibration device 10 is used in the electronic device 100 that gives tactile feedback to a user 200 by vibrating a vibrated member 2 when the user 200 presses the vibrated member 2. The vibrated member 2 vibrates when the user 200 presses the vibrated member 2, enabling the user 200 to feel the press of the vibrated member 2. As described above, the vibration device 10 is attached to the vibrated member 2.

A housing 1 is a rectangular parallelepiped box. As illustrated in FIG. 1, the housing 1 is provided with an opening OP. More specifically, the opening OP has a rectangular shape when viewed in the up-down direction. As illustrated in FIG. 1, the opening OP penetrates an upper surface of the housing 1 in the up-down direction.

As illustrated in FIG. 1, the vibrated member 2 has a plate shape. Therefore, the vibrated member 2 has an upper main surface US2 and a lower main surface LS2 arranged in the up-down direction. The upper main surface US2 is located above the lower main surface LS2. The upper main surface US2 and the lower main surface LS2 are parallel to each other. Each of the upper main surface US2 and the lower main surface LS2 has a rectangular shape having a long side extending in the left-right direction and a short side extending in the front-rear direction.

As illustrated in FIG. 1, a position in the up-down direction of the vibrated member 2 is equal to a position in the up-down direction of an upper surface of the housing 1. Further, the vibrated member 2 is located in the opening OP when viewed in the up-down direction. By the above, the user 200 can press the upper main surface US2 of the vibrated member 2. Note that the vibrated member 2 is not in contact with the housing 1.

As illustrated in FIG. 2, the vibration device 10 includes the support member 3, and the actuator 4. As illustrated in FIG. 3, the support member 3 includes the fixed portion 31, the movable portion 32, and the elastic coupling portion 33. The movable portion 32, the elastic coupling portion 33, and the fixed portion 31 are arranged in this order from left to right. A material of the support member 3 is metal such as stainless used steel (SUS). The support member 3 is manufactured by punching one SUS plate.

As illustrated in FIG. 1, the fixed portion 31 is fixed to the housing 1. More specifically, as illustrated in FIG. 3, the fixed portion 31 has two screw holes 311. The fixed portion 31 is fixed to the housing 1 as a bolt 5 is inserted into each of two of the screw holes 311 and each of two screw holes (not illustrated) of the housing 1 from below two of the screw holes 311.

As illustrated in FIG. 1, the movable portion 32 supports the vibrated member 2. The movable portion 32 has the upper main surface US32 and a lower main surface LS32 arranged in the up-down direction. The upper main surface US32 is located above the lower main surface LS32. The upper main surface US32 and the lower main surface LS32 are parallel to each other. As illustrated in FIG. 3, each of the upper main surface US32 and the lower main surface LS32 has a rectangular shape having a long side extending in the left-right direction and a short side extending in the front-rear direction.

As illustrated in FIG. 3, the movable portion 32 has a slit 321. The slit 321 penetrates the movable portion 32 in the up-down direction. The slit 321 has a shape extending in the front-rear direction when viewed in the up-down direction. The slit 321 has a rectangular shape having a short side extending in the left-right direction and a long side extending in the front-rear direction. The slit 321 overlaps the elastic coupling portion 33 when viewed in the left-right direction.

As illustrated in FIG. 3, the elastic coupling portion 33 elastically couples the fixed portion 31 and the movable portion 32 in the left-right direction. More specifically, the movable portion 32 is elastically coupled to the fixed portion 31 in the left-right direction via the elastic coupling portion 33. By the above, the movable portion 32 can vibrate in an optional direction with respect to the fixed portion 31. The optional direction is the left-right direction, the front-rear direction, the up-down direction, or the like. Therefore, the elastic coupling portion 33 has a first elastic coefficient k1 in the left-right direction and a second elastic coefficient k2 in the up-down direction. Further, the second elastic coefficient k2 is smaller than the first elastic coefficient k1.

As illustrated in FIG. 4, the elastic coupling portion 33 includes the first curved portion 331, the second curved portion 332, the third curved portion 333, a first coupling portion 334, and a second coupling portion 335. Each of the first curved portion 331, the second curved portion 332, and the third curved portion 333 is elastically deformed. Further, the first curved portion 331, the second curved portion 332, and the third curved portion 333 are arranged in this order from left to right when viewed in the front-rear direction.

As illustrated in FIG. 4, the first curved portion 331 has a shape curved so as to project in the front direction. Further, a left end portion of the first curved portion 331 has a shape extending in the front-rear direction. Therefore, the elastic coupling portion 33 includes a shape extending in the front-rear direction. Further, a right end portion of the first curved portion 331 has a shape extending from a front-right direction to a rear-left direction.

As illustrated in FIG. 4, the second curved portion 332 has a shape curved so as to project in a rear direction. The second curved portion 332 has an inner edge I332 and an outer edge O332. Each of the inner edge I332 and the outer edge O332 is an inner edge of an arc and an outer edge of an arc. Therefore, length of the outer edge O332 is longer than the length of the inner edge I332, and a radius of curvature of the outer edge O332 is equal to a radius of curvature of the inner edge I332. Further, a left end portion of the second curved portion 332 has a shape extending from the front-right direction to the rear-left direction. Further, a right end portion of the second curved portion 332 has a shape extending from a front-let direction to a rear-right direction.

As illustrated in FIG. 4, the third curved portion 333 has a shape curved so as to project in the front direction. Further, a left end portion of the third curved portion 333 has a shape extending from the front-let direction to the rear-right direction. Further, a right end portion of the third curved portion 333 has a shape extending in the front-rear direction.

As illustrated in FIG. 4, a shortest distance LRMIN13 in the left-right direction between the first curved portion 331 and the third curved portion 333 is shorter than a longest distance LRMAXO2 in the left-right direction of the outer edge O332 of the second curved portion 332.

As illustrated in FIGS. 3 and 4, the first coupling portion 334 couples the movable portion 32 and the first curved portion 331. As illustrated in FIG. 4, the first coupling portion 334 has a shape extending in a first direction DIR1. Note that the first coupling portion 334 only needs to have a shape extending in the first direction DIR1.

As illustrated in FIG. 4, the first direction DIR1 forms a first angle θ1 counterclockwise with respect to the left-right direction when viewed in the up-down direction. The first angle θ1 is an angle larger than 0 degrees counterclockwise and smaller than 90 degrees counterclockwise. That is, the first direction DIR1 is different from the left-right direction when viewed in the up-down direction. In the present embodiment, the first angle θ1 is an angle larger than 30 degrees counterclockwise and smaller than 90 degrees counterclockwise.

As illustrated in FIGS. 3 and 4, the second coupling portion 335 couples the fixed portion 31 and the third curved portion 333. As illustrated in FIG. 4, the second coupling portion 335 has a shape extending in a second direction DIR2. Note that the second coupling portion 335 only needs to have a shape extending in the second direction DIR2.

As illustrated in FIG. 4, the second direction DIR2 forms a second angle θ2 clockwise with respect to the left-right direction when viewed in the up-down direction. The second angle θ2 is an angle larger than 0 degrees clockwise and smaller than 90 degrees clockwise. That is, the second direction DIR2 is different from the left-right direction when viewed in the up-down direction. In the present embodiment, the second angle θ2 is an angle larger than 30 degrees clockwise and smaller than 90 degrees clockwise.

As illustrated in FIG. 5, the actuator 4 includes a piezoelectric film 41, a first electrode (not illustrated), and a second electrode (not illustrated). The actuator 4 has a film shape.

As illustrated in FIG. 1, the actuator 4 has a first main surface US4 and a second main surface LS4. The first main surface US4 is located above the second main surface LS4. The first main surface US4 and the second main surface LS4 are parallel to each other. The first main surface US4 is an upper surface of the first electrode. The second main surface LS4 is a lower surface of the second electrode. As illustrated in FIG. 5, each of the first main surface US4 and the second main surface LS4 has a rectangular shape having a long side extending in the left-right direction and a short side extending in the front-rear direction when viewed in the up-down direction.

The piezoelectric film 41 is a piezoelectric body. That is, the actuator 4 includes a piezoelectric body. Further, the piezoelectric film 41 has an upper surface and a lower surface. The first electrode is provided on an upper surface of the piezoelectric film 41 (not illustrated). The second electrode is provided on a lower surface of the piezoelectric film 41 (not illustrated). Each of the first electrode and the second electrode is a metal film formed by vapor deposition.

As illustrated in FIG. 2, the actuator 4 is attached to the fixed portion 31 of the support member 3 and the movable portion 32 of the support member 3. More specifically, a left end portion of the actuator 4 is attached to the movable portion 32 by an adhesive (not illustrated) in a state where the actuator 4 is slightly extended in the left-right direction, and a right end portion of the actuator 4 is attached to the fixed portion 31 by an adhesive (not illustrated) in a state where the actuator 4 is slightly extended in the left-right direction.

When AC voltage is applied to the actuator 4, the actuator 4 stretches and contracts in the left-right direction. More specifically, when AC voltage is applied between the first electrode and the second electrode, the piezoelectric film 41 stretches and contracts in the left-right direction. For example, when positive voltage is applied to the actuator 4, the actuator 4 is stretched in the left-right direction. On the other hand, when negative voltage is applied to the actuator 4, the actuator 4 contracts in the left-right direction. Therefore, when AC voltage is applied to the actuator 4, the actuator 4 vibrates in the left-right direction. By the above, the actuator 4 vibrates the vibrated member 2 and the movable portion 32 of the support member 3 in the left-right direction. Note that AC voltage is voltage in which polarity cyclically changes between positive and negative.

### Effect

As illustrated in FIG. 6, a situation in which the vibration device 1010 according to a comparative example falls and the vibration device 1010 according to the comparative example collides with the floor 6 in a state where the fixed portion 31 is above the movable portion 32 is assumed. Hereinafter, the up-down direction in FIGS. 6 and 7 is defined as a vertical up-down direction. A direction u in FIGS. 6 and 7 is defined as a vertical upward direction, and a direction d in FIGS. 6 and 7 is defined as a vertical downward direction. Further, the left-right direction and the front-rear direction in FIGS. 6 and 7 are defined as a horizontal left-right direction and a horizontal front-rear direction, respectively. A direction 1 in FIGS. 6 and 7 is defined as a horizontal left direction, and a direction r in FIGS. 6 and 7 is defined as a horizontal right direction. Further, a direction f in FIGS. 6 and 7 is defined as a horizontal front direction, and a direction b in FIGS. 6 and 7 is defined as a horizontal rear direction. The vertical up-down direction coincides with the left-right direction. The horizontal left-right direction coincides with the front-rear direction. The horizontal front-rear direction coincides with the up-down direction. The vertical up-down direction, the horizontal left-right direction, and the horizontal front-rear direction are orthogonal to each other.

The vibration device 1010 according to the comparative example is different from the vibration device 10 in that the second elastic coefficient k2 is equal to or more than the first elastic coefficient k1. Note that a shape of the vibration device 1010 according to the comparative example is an example. When the vibration device 1010 according to the comparative example collides with the floor 6, the vibration device 1010 according to the comparative example receives impact force F from the floor 6, and the elastic coupling portion 33 also receives the impact force F. The second elastic coefficient k2 is equal to or more than the first elastic coefficient k1. By the above, the elastic coupling portion 33 is more easily deformed in the left-right direction than in the up-down direction. For this reason, the elastic coupling portion 33 contracts in the vertical up-down direction (the left-right direction in FIGS. 1 to 5). This causes slack in the actuator 4. Therefore, vibration of the actuator 4 is less likely to be transmitted to the vibrated member 2.

In view of the above, in the vibration device 10, the second elastic coefficient k2 is smaller than the first elastic coefficient k1. By the above, the elastic coupling portion 33 is more easily deformed in the up-down direction than in the left-right direction. For this reason, when the vibration device 10 collides with the floor 6, the elastic coupling portion 33 can be elastically deformed in the horizontal front-rear direction (up-down direction in FIGS. 1 to 5) in addition to the vertical up-down direction (left-right direction in FIGS. 1 to 5). Therefore, according to the vibration device 10, an elastic region of the elastic coupling portion 33 is enlarged. For this reason, larger force is required to plastically deform the elastic coupling portion 33. Therefore, according to the vibration device 10, the elastic coupling portion 33 is less likely to be plastically deformed. As a result, according to the vibration device 10, fall resistance of the vibration device can be improved.

According to the vibration device 10, fall resistance of the vibration device can be further improved. More specifically, the elastic coupling portion 33 includes the first curved portion 331 that is elastically deformed, the second curved portion 332 that is elastically deformed, and the third curved portion 333 that is elastically deformed. Further, the first curved portion 331, the second curved portion 332, and the third curved portion 333 are arranged in this order from left to right when viewed in the front-rear direction. The first curved portion 331 and the third curved portion 333 include a shape curved so as to project in the front direction, and the second curved portion 332 includes a shape curved so as to project in the rear direction. By the above, when the vibration device 10 collides with the floor 6, the second curved portion 332 can be elastically deformed in the horizontal front-rear direction (up-down direction in FIGS. 1 to 5). More specifically, both ends of the second curved portion 332 are not fixed. By the above, the outer edge O332 of the second curved portion 332 and the inner edge I332 of the second curved portion 332 are easily deformed in the up-down direction. Therefore, the elastic coupling portion 33 is easily elastically deformed and likely to undergo twist deformation in the horizontal front-rear direction (up-down direction in FIGS. 1 to 5), and an elastic region of the elastic coupling portion 33 is enlarged. For this reason, larger force is required to plastically deform the elastic coupling portion 33. Therefore, according to the vibration device 10, the elastic coupling portion 33 is less likely to be plastically deformed. As a result, according to the vibration device 10, fall resistance of the vibration device can be further improved.

According to the vibration device 10, fall resistance of the vibration device can be further improved. More specifically, the shortest distance LRMIN13 in the left-right direction between the first curved portion 331 and the third curved portion 333 is shorter than the longest distance LRMAXO2 in the left-right direction of the outer edge O332 of the second curved portion 332. By the above, each of a right end portion of the first curved portion 331 and a left end portion of the second curved portion 332 has a shape extending from the front-right direction to the rear-left direction. Further, each of a right end portion of the second curved portion 332 and a left end portion of the third curved portion 333 has a shape extending from the front-left direction to the rear-right direction. When the vibration device 10 collides with the floor 6, the force F1 acts on each of a right end portion of the first curved portion 331, a left end portion of the second curved portion 332, a right end portion of the second curved portion 332, and a left end portion of the third curved portion 333 as illustrated in FIG. 7. By the above, the shortest distance LRMIN13 in the left-right direction between the first curved portion 331 and the third curved portion 333 is shortened, and the second curved portion 332 is easily warped in the horizontal front-rear direction (the up-down direction in FIGS. 1 to 5). Therefore, the second curved portion 332 is easily elastically deformed in the horizontal front-rear direction (the up-down direction in FIGS. 1 to 5). For this reason, larger force is required to plastically deform the elastic coupling portion 33. Therefore, according to the vibration device 10, the elastic coupling portion 33 is less likely to be plastically deformed. As a result, according to the vibration device 10, fall resistance of the vibration device can be further improved.

According to the vibration device 10, fall resistance of the vibration device can be further improved. More specifically, the first coupling portion 334 includes a shape extending in the first direction DIR1. The first direction DIR1 forms an angle larger than 0 degrees counterclockwise and smaller than 90 degrees counterclockwise with respect to the left-right direction when viewed in the up-down direction. By the above, when the vibration device 10 collides with the floor 6, the force F2 acts on the first coupling portion 334 as illustrated in FIG. 7. The force F2 causes twisting between the first coupling portion 334 and the first curved portion 331. By the above, the first curved portion 331 is twisted with respect to the first curved portion 331, and as a result, the second curved portion 332 is likely undergo twist deformation in the horizontal front-rear direction (up-down direction in FIGS. 1 to 5). Therefore, the elastic coupling portion 33 is easily elastically deformed and likely to undergo twist deformation in the horizontal front-rear direction (up-down direction in FIGS. 1 to 5), and an elastic region of the elastic coupling portion 33 is enlarged. For this reason, larger force is required to plastically deform the elastic coupling portion 33. Therefore, according to the vibration device 10, the elastic coupling portion 33 is less likely to be plastically deformed. As a result, according to the vibration device 10, fall resistance of the vibration device can be further improved.

According to the vibration device 10, fall resistance of the vibration device can be further improved. More specifically, the second coupling portion 335 includes a shape extending in the second direction DIR2. The second direction DIR2 forms an angle larger than 0 degrees clockwise and smaller than 90 degrees clockwise with respect to the left-right direction when viewed in the up-down direction. By the above, when the vibration device 10 collides with the floor 6, the force F3 acts on the second coupling portion 335 as illustrated in FIG. 7. The force F3 causes twisting between the second coupling portion 335 and the third curved portion 333. By the above, the third curved portion 333 is twisted with respect to the second coupling portion 335, and as a result, the second curved portion 332 is likely undergo twist deformation in the horizontal front-rear direction (up-down direction in FIGS. 1 to 5). Therefore, the elastic coupling portion 33 is easily elastically deformed and likely to undergo twist deformation in the horizontal front-rear direction (up-down direction in FIGS. 1 to 5), and an elastic region of the elastic coupling portion 33 is enlarged. For this reason, larger force is required to plastically deform the elastic coupling portion 33. Therefore, according to the vibration device 10, the elastic coupling portion 33 is less likely to be plastically deformed. As a result, according to the vibration device 10, fall resistance of the vibration device can be further improved.

According to the vibration device 10, fall resistance of the vibration device can be further improved. More specifically, the movable portion 32 has the slit 321 penetrating the movable portion 32 in the up-down direction. The slit 321 has a shape extending in the front-rear direction when viewed in the up-down direction. Further, the slit 321 overlaps the elastic coupling portion 33 when viewed in the left-right direction. By the above, in the movable portion 32, a portion located between the slit 321 and the elastic coupling portion 33 is easily deformed. By the above, the impact force F received by the vibration device 10 from the floor 6 is dispersed into force contributing to deformation of the elastic coupling portion 33 and force contributing to deformation of the movable portion 32. For this reason, larger force is required to plastically deform the elastic coupling portion 33. Therefore, according to the vibration device 10, the elastic coupling portion 33 is less likely to be plastically deformed. As a result, according to the vibration device 10, fall resistance of the vibration device can be further improved.

### Other Embodiments

The vibration device according to the present disclosure is not limited to the vibration device 10, and can be modified in the scope of the gist of the present disclosure.

Note that, as illustrated in FIG. 1, the vibration device 10 and the vibrated member 2 may be modularized to form a vibration device 20.

Note that, as illustrated in FIG. 1, the vibration device 10 and the housing 1 may be modularized to form an electronic device 30.

Note that, as illustrated in FIG. 1, the vibration device 10, the housing 1, and the vibrated member 2 may be modularized to form the electronic device 100. Note that the use application of the electronic device 100 is not limited to providing tactile feedback to the user 200.

Note that the actuator 4 may be attached to the fixed portion 31 of the support member 3 and the vibrated member 2.

Note that the first direction DIR1 may form the first angle θ1 larger than 45 degrees counterclockwise and smaller than 90 degrees counterclockwise with respect to the left-right direction when viewed in the up-down direction. Further, the second direction DIR2 may form the second angle θ2 larger than 45 degrees clockwise and smaller than 90 degrees clockwise with respect to the left-right direction when viewed in the up-down direction. Even in this case, fall resistance of the vibration device can be further improved.

Note that the first direction DIR1 may form the first angle θ1 larger than 60 degrees counterclockwise and smaller than 90 degrees counterclockwise with respect to the left-right direction when viewed in the up-down direction. Further, the second direction DIR2 may form the second angle θ2 larger than 60 degrees clockwise and smaller than 90 degrees clockwise with respect to the left-right direction when viewed in the up-down direction. Even in this case, fall resistance of the vibration device can be further improved.

Note that the vibration device 10 is not limited to being used for the electronic device 100.

Note that the vibrated member 2 may be pressed by an operation member without limited to the user 200.

Note that the housing 1 is not limited to a rectangular parallelepiped box.

Note that the opening OP does not need to have a rectangular shape in the up-down direction.

Note that the vibrated member 2 does not need to have a plate shape. The vibrated member 2 does not need to have the upper main surface US2 or the lower main surface LS2 arranged in the up-down direction. Further, the upper main surface US2 and the lower main surface LS2 do not need to be parallel to each other.

Note that each of the upper main surface US2 and the lower main surface LS2 does not need to have a rectangular shape having a long side extending in the left-right direction and a short side extending in the front-rear direction.

Note that a position of the vibrated member 2 in the up-down direction does not need to be equal to a position of the upper surface of the housing 1 in the up-down direction.

Note that the vibrated member 2 does not need to be located in the opening OP when viewed in the up-down direction.

Note that the vibrated member 2 may be in contact with the housing 1.

Note that a material of the support member 3 does not need to be metal such as stainless used steel (SUS).

Note that the support member 3 does not need to be manufactured by punching one SUS plate.

Note that the fixed portion 31 may be fixed to the housing 1 with an adhesive. Therefore, the fixed portion 31 does not need to have the screw hole 311. Further, the housing 1 does not need to have a screw hole. Further, the bolt 5 is not an essential constituent element.

Note that in a case where the fixed portion 31 has the screw holes 311, two or more of the screw holes 311 are preferably provided. In a case where the number of the screw holes 311 is one, the fixed portion 31 is easily rotated about the screw hole 311 when viewed in the up-down direction by vibration of the actuator 4. In a case where the fixed portion 31 rotates about the screw hole 311 when viewed in the up-down direction by vibration of the actuator 4, a part of vibration energy that causes the actuator 4 to vibrate the vibrated member 2 and the movable portion 32 of the support member 3 in the left-right direction is consumed by the rotation of the fixed portion 31. By the above, efficiency of the actuator 4 vibrating the vibrated member 2 and the movable portion 32 of the support member 3 in the left-right direction is lowered. On the other hand, as the fixed portion 31 has two or more of the screw holes 311, a part of the vibration energy can be prevented from being consumed by the rotation of the fixed portion 31. As the fixed portion 31 has two or more of the screw holes 311, the actuator 4 can efficiently vibrate the vibrated member 2 and the movable portion 32 of the support member 3 in the left-right direction.

Note that the upper main surface US32 and the lower main surface LS32 do not need to be parallel to each other.

Note that each of the upper main surface US32 and the lower main surface LS32 does not need to have a rectangular shape having a long side extending in the left-right direction and a short side extending in the front-rear direction.

Note that the slit 321 does not need to have a rectangular shape having a short side extending in the left-right direction and a long side extending in the front-rear direction.

Note that the actuator 4 does not need to include a piezoelectric body. The actuator 4 may be, for example, a linear resonant actuator (LRA).

Note that a radius of curvature of the outer edge O332 does not need to be equal to a radius of curvature of the inner edge I332.

Note that in the present embodiment, fall resistance means resistance to plastic deformation.

The present disclosure has a structure below.
(1) A vibration device including: a support member that includes a fixed portion, a movable portion having an upper main surface and a lower main surface arranged in an up-down direction, the movable portion constructed to support a vibrated member; an actuator attached to the fixed portion and the movable portion or the vibrated member, and constructed to vibrate the vibrated member in a left-right direction; an elastic coupling portion that elastically couples the fixed portion and the movable portion in a left-right direction, the elastic coupling portion having a first elastic coefficient in the left-right direction and a second elastic coefficient in the up-down direction, and the second elastic coefficient is smaller than the first elastic coefficient.
(2) The vibration device according to (1), in which the elastic coupling portion includes a first curved elastically deformable portion, a second curved elastically deformable portion, and a third curved elastically deformable portion, the first curved elastically deformable portion, the second curved elastically deformable portion, and the third curved elastically deformable portion are arranged in this order from left to right when viewed in a front-rear direction, the first curved elastically deformable portion and the third curved elastically deformable portion include a shape that is curved so as to project in a front direction, and the second curved elastically deformable portion includes a shape that is curved so as to project in a rear direction.
(3) The vibration device according to (2), in which a shortest distance in the left-right direction between the first curved elastically deformable portion and the third curved elastically deformable portion is shorter than a longest distance in the left-right direction of an outer edge of the second curved elastically deformable portion.
(4) The vibration device according to (2) or (3), in which the elastic coupling portion further includes a first coupling portion that couples the movable portion and the first curved portion, the first coupling portion includes a first shape extending in a first direction, and the first direction forms a first angle larger than 0 degrees counterclockwise and smaller than 90 degrees counterclockwise with respect to the left-right direction when viewed in the up-down direction.
(5) The vibration device according to (4), in which the first angle is larger than 30 degrees counterclockwise and smaller than 90 degrees counterclockwise with respect to the left-right direction when viewed in the up-down direction.
(6) The vibration device according to (4), in which the first angle is larger than 45 degrees counterclockwise and smaller than 90 degrees counterclockwise with respect to the left-right direction when viewed in the up-down direction.
(7) The vibration device according to (4), in which the first angle is larger than 60 degrees counterclockwise and smaller than 90 degrees counterclockwise with respect to the left-right direction when viewed in the up-down direction.
(8) The vibration device according to any of (2) to (7), in which the elastic coupling portion further includes a second coupling portion that couples the fixed portion and the third curved elastically deformable portion, the second coupling portion includes a second shape extending in a second direction, and the second direction forms a second angle larger than 0 degrees clockwise and smaller than 90 degrees counterclockwise with respect to the left-right direction when viewed in the up-down direction.
(9) The vibration device according to (8), in which the second angle is larger than 30 degrees clockwise and smaller than 90 degrees counterclockwise with respect to the left-right direction when viewed in the up-down direction.
(10) The vibration device according to (8), in which the second angle is larger than 45 degrees clockwise and smaller than 90 degrees counterclockwise with respect to the left-right direction when viewed in the up-down direction.
(11) The vibration device according to (8), in which the second angle is larger than 60 degrees clockwise and smaller than 90 degrees counterclockwise with respect to the left-right direction when viewed in the up-down direction.
(12) The vibration device according to any of (1) to (11), in which the movable portion includes a slit penetrating the movable portion in the up-down direction, the slit has a shape extending in the front-rear direction when viewed in the up-down direction, and the slit overlaps the elastic coupling portion when viewed in the left-right direction.
(13) The vibration device according to any of (1) to (12), in which the elastic coupling portion includes a shape extending in the front-rear direction.
(14) The vibration device according to any of (1) to (13), in which the actuator includes a piezoelectric film.
(15) The vibration device according to any of (1) to (14), further including the vibrated member.
(16) An electronic device including: the vibration device according to any of (1) to (15); and a housing that supports the fixed portion.

### DESCRIPTION OF REFERENCE SYMBOLS

1: Housing
2: Vibrated member
3: Support member
4: Actuator
5: Bolt
6: Floor
10, 20: Vibration device
30, 100: Electronic device
31: Fixed portion
32: Movable portion
33: Elastic coupling portion
41: Piezoelectric film
200: User
311: Screw hole
321: Slit
331: First curved portion
332: Second curved portion
333: Third curved portion
334: First coupling portion
335: Second coupling portion
DIR1: First direction
DIR2: Second direction
F: Impact force
F1, F2, F3: Force
I332: Inner edge
LRMAXO2: Longest distance
LRMIN13: Shortest distance
LS2, LS32: Lower main surface
LS4: Second main surface
O332: Outer edge
OP: Opening
US2, US32: Upper main surface
US4: First main surface
k1: First elastic coefficient
k2: Second elastic coefficient
θ1: First angle
θ2: Second angle

1. A vibration device comprising:
a support member that includes:
a fixed portion;
a movable portion having an upper main surface and a lower main surface arranged in an up-down direction, the movable portion constructed to support a vibrated member;
an actuator attached to the fixed portion and the movable portion or the vibrated member, and constructed to vibrate the vibrated member in a left-right direction;
an elastic coupling portion that elastically couples the fixed portion and the movable portion in a left-right direction, the elastic coupling portion having a first elastic coefficient in the left-right direction and a second elastic coefficient in the up-down direction, and the second elastic coefficient is smaller than the first elastic coefficient.

2. The vibration device according to claim 1, wherein
the elastic coupling portion includes a first curved elastically deformable portion, a second curved elastically deformable portion, and a third curved elastically deformable portion,
the first curved elastically deformable portion, the second curved elastically deformable portion, and the third curved elastically deformable portion are arranged in this order from left to right when viewed in a front-rear direction,
the first curved elastically deformable portion and the third curved elastically deformable portion include a shape that is curved so as to project in a front direction, and
the second curved elastically deformable portion includes a shape that is curved so as to project in a rear direction.

3. The vibration device according to claim 2, wherein a shortest distance in the left-right direction between the first curved elastically deformable portion and the third curved elastically deformable portion is shorter than a longest distance in the left-right direction of an outer edge of the second curved elastically deformable portion.

4. The vibration device according to claim 2, wherein
the elastic coupling portion further includes a first coupling portion that couples the movable portion and the first curved portion,
the first coupling portion includes a first shape extending in a first direction that forms a first angle larger than 0 degrees counterclockwise and smaller than 90 degrees counterclockwise with respect to the left-right direction when viewed in the up-down direction.

5. The vibration device according to claim 4, wherein the first angle is larger than 30 degrees counterclockwise and smaller than 90 degrees counterclockwise with respect to the left-right direction when viewed in the up-down direction.

6. The vibration device according to claim 4, wherein the first angle is larger than 45 degrees counterclockwise and smaller than 90 degrees counterclockwise with respect to the left-right direction when viewed in the up-down direction.

7. The vibration device according to claim 4, wherein the first angle is larger than 60 degrees counterclockwise and smaller than 90 degrees counterclockwise with respect to the left-right direction when viewed in the up-down direction.

8. The vibration device according to claim 2, wherein
the elastic coupling portion further includes a second coupling portion that couples the fixed portion and the third curved elastically deformable portion,
the second coupling portion includes a second shape extending in a second direction, and the second direction forms a second angle larger than 0 degrees clockwise and smaller than 90 degrees counterclockwise with respect to the left-right direction when viewed in the up-down direction.

9. The vibration device according to claim 8, wherein the second angle is larger than 30 degrees clockwise and smaller than 90 degrees counterclockwise with respect to the left-right direction when viewed in the up-down direction.

10. The vibration device according to claim 8, wherein the second angle is larger than 45 degrees clockwise and smaller than 90 degrees counterclockwise with respect to the left-right direction when viewed in the up-down direction.

11. The vibration device according to claim 8, wherein the second angle is larger than 60 degrees clockwise and smaller than 90 degrees counterclockwise with respect to the left-right direction when viewed in the up-down direction.

12. The vibration device according to claim 2, wherein the elastic coupling portion further includes:
a first coupling portion that couples the movable portion and the first curved portion; and
a second coupling portion that couples the fixed portion and the third curved elastically deformable portion, wherein
the first coupling portion includes a first shape extending in a first direction that forms a first angle larger than 0 degrees counterclockwise and smaller than 90 degrees counterclockwise with respect to the left-right direction when viewed in the up-down direction, and
the second coupling portion includes a second shape extending in a second direction, and the second direction forms a second angle larger than 0 degrees clockwise and smaller than 90 degrees counterclockwise with respect to the left-right direction when viewed in the up-down direction.

13. The vibration device according to claim 12, wherein the first angle is larger than 30 degrees counterclockwise and smaller than 90 degrees counterclockwise with respect to the left-right direction when viewed in the up-down direction, and the second angle is larger than 30 degrees clockwise and smaller than 90 degrees counterclockwise with respect to the left-right direction when viewed in the up-down direction.

14. The vibration device according to claim 12, wherein the first angle is larger than 45 degrees counterclockwise and smaller than 90 degrees counterclockwise with respect to the left-right direction when viewed in the up-down direction, and the second angle is larger than 45 degrees clockwise and smaller than 90 degrees counterclockwise with respect to the left-right direction when viewed in the up-down direction.

15. The vibration device according to claim 12, wherein the first angle is larger than 60 degrees counterclockwise and smaller than 90 degrees counterclockwise with respect to the left-right direction when viewed in the up-down direction, and the second angle is larger than 60 degrees clockwise and smaller than 90 degrees counterclockwise with respect to the left-right direction when viewed in the up-down direction.

16. The vibration device according to claim 1, wherein
the movable portion includes a slit penetrating the movable portion in the up-down direction,
the slit has a shape extending in the front-rear direction when viewed in the up-down direction, and
the slit overlaps the elastic coupling portion when viewed in the left-right direction.

17. The vibration device according to claim 1, wherein the elastic coupling portion includes a shape extending in the front-rear direction.

18. The vibration device according to claim 1, wherein the actuator includes a piezoelectric film.

19. The vibration device according to claim 1, further comprising the vibrated member.

20. An electronic device comprising:
the vibration device according to claim 1; and
a housing that supports the fixed portion.
